(19) United States
(12) Patent Application Publication
(10) Pub. No.: US 2025/0070730 A1
(43) Pub. Date: Feb. 27, 2025

(54) LOW VOLTAGE PA BIAS NETWORK

(71) Applicant: Qorvo US, Inc., Greensboro, NC (US)

(72) Inventors: Marcus Granger-Jones, Scotts Valley, CA (US); Shruti Bohara, Santa Clara, CA (US); Toshiaki Moriuchi, San Jose, CA (US)

(21) Appl. No.: 18/811,986

(22) Filed: Aug. 22, 2024

Related U.S. Application Data
(60) Provisional application No. 63/534,188, filed on Aug. 23, 2023.

(51) Int. Cl. H03F 3/24

(52) U.S. Cl. CPC H03F 3/245; H03F 2200/451

(57) ABSTRACT

Embodiments of a power amplification device are disclosed. The power amplification device includes a power amplification circuit configured to amplify a radio frequency (RF) input signal and generate an amplified RF output signal. The power amplification device also includes a bias circuit. The bias circuit is provided in a closed loop configuration that has a bipolar junction transistor (BJT) that generates the bias voltage applied to the RF input signal. The BJT is provided in a common emitter configuration. This allows for the bias voltage generated by the bias circuit to be generated with a power voltage having a lower voltage level.

### RELATED APPLICATIONS

This application claims the benefit of provisional patent application Ser. No. 63/534,188, filed Aug. 23, 2023, the disclosure of which is hereby incorporated herein by reference in its entirety.

### FIELD OF THE DISCLOSURE

This disclosure relates generally to power amplification devices in radio frequency (RF) devices and methods of operating the same.

### BACKGROUND

Power amplification devices include bias networks to provide a bias voltage and a bias current to a radio frequency (RF) signal that is to be amplified by a power amplifier in the power amplification device. Power amplifiers used in portable user devices (i.e., smart phone and tables) are now being requested to work at supply voltages as low as 2.5 Volts (V) to ensure that the portable user device is still able to transmit an amplified RF signal when there is a temporary droop in the power voltage. The droop in the power voltage can occur during or after a user device's camera light (i.e., camera flash) is activated.

This problem is particularly important if the power amplifier includes a Heterojunction Bipolar Transistor (HBT). Bias networks utilizing this technology generally have a minimum voltage requirement of around 2.8V. This is because a minimum voltage of 2 times of a base-emitter voltage level (VBE) is required in order to apply 1 times VBE to the input of the power amplifier. This puts power amplifiers that use HBTs at a competitive disadvantage.

### SUMMARY

In some embodiments, a power amplification device includes: a power node configured to receive a power voltage; a power amplifier that includes a power amplifier input configured to receive a radio frequency (RF) input signal; and a bias circuit that includes: a feedback circuit configured to receive a feedback input voltage that indicates a bias voltage applied to the power amplifier input of the power amplifier and to receive a reference voltage; a bias node coupled to the power amplifier input, wherein the bias voltage applied to the power amplifier input is generated at the bias node; a bipolar junction transistor (BJT) in a common emitter configuration, wherein the BJT includes a base connected to receive a control voltage from the feedback circuit, an emitter, and a collector, wherein the collector is coupled to the bias node; and a resistor connected between the power node and the bias node, wherein the feedback circuit is configured to generate the control voltage such that the bias voltage is set in accordance with the reference voltage.

In some embodiments, an input voltage is generated from the bias voltage which is generated at the bias node and the RF input signal is applied to the power amplifier input. In some embodiments, the emitter is connected to ground. In some embodiments, the power amplifier is a Heterojunction Bipolar Transistor (HBT) having a second base, a second emitter, and a second collector; the base is a first base, the emitter is a first emitter, and the collector is a first collector; the power amplifier input is the second base; and the bias circuit is configured to receive a regulated voltage and the regulated voltage is between 1.8 Volts and 2.7 Volts. In some embodiments, the feedback circuit includes a differential amplifier configured to receive the feedback input voltage and the reference voltage, wherein the differential amplifier is further configured to generate the control voltage such that the bias voltage is set in accordance with the reference voltage.

In some embodiments, the power amplification device further includes: a second resistor connected between the power node and a feedback input node, wherein the differential amplifier is configured to receive the feedback input voltage at the feedback input node and wherein the resistor is a first resistor; a second BJT having a second base, a second collector, and a second emitter, wherein: the base is a first base, the collector is a first collector, and the emitter is a first emitter; the second base is coupled to the first base; the second collector is connected to the feedback input node; and the second emitter is connected to ground.

In some embodiments, a dominant pole filter is connected between the second base and the power amplifier input. In some embodiments, the BJT is a first BJT, the base is a first base, the emitter is a first emitter, the collector is a first collector, and wherein the differential amplifier includes: a second BJT and a third BJT that form a differential pair; the second BJT having a second base that is configured to receive the feedback input voltage, a second collector that is coupled to the power node, a second emitter that is connected to a differential pair biasing node that receives a second bias voltage, and wherein the bias voltage is a first bias voltage; and the third BJT has a third base that is configured to receive the reference voltage, a third collector that is coupled to the power node, and a third emitter that is connected to the differential pair biasing node that receives the second bias voltage.

In some embodiments, the feedback circuit further includes a differential pair biasing circuit that is configured to generate a bias current. In some embodiments, the differential pair biasing circuit includes a current mirror that includes: a fourth BJT having a fourth collector connected to the differential pair biasing node, a fourth emitter coupled to ground, and a fourth base; a fifth BJT having a fifth base connected to the fourth base, a fifth collector directly connected to the fifth base, and a fifth emitter coupled to the ground; and a third resistor connected between the power node and the fifth collector. In some embodiments, the power amplification device further includes a base-emitter voltage level (VBE) multiplying circuit configured to generate the reference voltage as a temperature dependent reference voltage. In some embodiments, the resistor is a first resistor, the BJT is a first BJT, the base is a first base, the collector is a first collector, the emitter is a first emitter, and wherein the VBE multiplying circuit includes: a second resistor; a third resistor; and a second BJT having a second base, a second collector, a second emitter, and wherein: the second collector is connected to the feedback circuit such that the reference voltage is generated at the second collector; the second resistor is connected between the second collector and the second base; and the third resistor is connected between the second base and ground. In some embodiments, the second BJT is thermally coupled to the power amplifier and the bias circuit.

In some embodiments, a power amplification device includes: a power node configured to receive a power voltage; an HBT that includes a first base configured to receive an RF input signal, a first collector configured to output an RF output signal, and a first emitter connected to ground; and a bias circuit includes: a feedback circuit configured to receive a feedback input voltage that indicates a bias voltage applied to the first base of the HBT and to receive a reference voltage; a resistor coupled to a power node, wherein the power node is configured to receive a power voltage; a BJT in a common emitter configuration, wherein the BJT includes a second base connected to receive a control voltage from the feedback circuit, a second emitter coupled to the ground, a second collector, and wherein the second collector and the resistor are connected to apply the bias voltage to the first base; and wherein the feedback circuit is configured to generate the control voltage such that the bias voltage is set in accordance with the reference voltage.

In some embodiments, the feedback circuit includes a differential amplifier configured to receive the feedback input voltage and the reference voltage, wherein the differential amplifier is further configured to generate the control voltage such that the bias voltage is set in accordance with the reference voltage. In some embodiments, the power amplification device further includes a second resistor connected between the power node and a feedback input node, wherein the differential amplifier is configured to receive the feedback input voltage at the feedback input node, and wherein the resistor is a first resistor; and a second BJT having a third base, a third collector, a third emitter, and wherein: the third base is coupled the first base; the third collector is connected to the feedback input node; and the third emitter is connected to the ground.

In some embodiments, a dominant pole filter is connected between a third base and a power amplifier input. In some embodiments, the BJT is a first BJT and wherein the differential amplifier includes: a second BJT and a third BJT that form a differential pair; the second BJT having a third base that is configured to receive the feedback input voltage, a third collector that is coupled to the power node, a third emitter that is connected to a differential pair biasing node that receives a second bias voltage, and the bias voltage being a first bias voltage; and the third BJT has a fourth base that is configured to receive the reference voltage, a fourth collector that is coupled to the power node, and a fourth emitter that is connected to the differential pair biasing node that receives the second bias voltage.

In some embodiments, the feedback circuit further includes a differential pair biasing circuit that is configured to generate the second bias voltage. In some embodiments, the bias circuit is configured to receive a regulated voltage and the regulated voltage is between 1.8 Volts and 2.7 Volts.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a power amplification device, in accordance with some embodiments; and

FIG. 2 illustrates a power amplification device, in accordance with some embodiments.

### DETAILED DESCRIPTION

The following disclosure provides many different embodiments, or examples, for implementing different features of the provided subject matter. Specific examples of components, values, operations, materials, arrangements, or the like are described below to simplify the present disclosure. These are, of course, merely examples and are not intended to be limiting. Other components, values, operations, materials, arrangements, or the like are contemplated. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself indicate a relationship between the various embodiments and/or configurations discussed.

Further, spatially relative terms such as “beneath,” “below,” “lower,” “above,” “upper,” and the like may be used herein for ease of description to describe one element's or feature's relationship to other element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of a power amplification device are disclosed. The power amplification device includes a power amplification circuit configured to amplify a radio frequency (RF) input signal and generate an amplified RF output signal. The power amplification device also includes a bias circuit. The bias circuit is provided in a closed loop configuration that has a bipolar junction transistor (BJT) which generates the bias voltage applied to the RF input signal. The BJT is provided in a common emitter configuration. This allows for the bias voltage generated by the bias circuit to be generated with a power voltage having a lower voltage level.

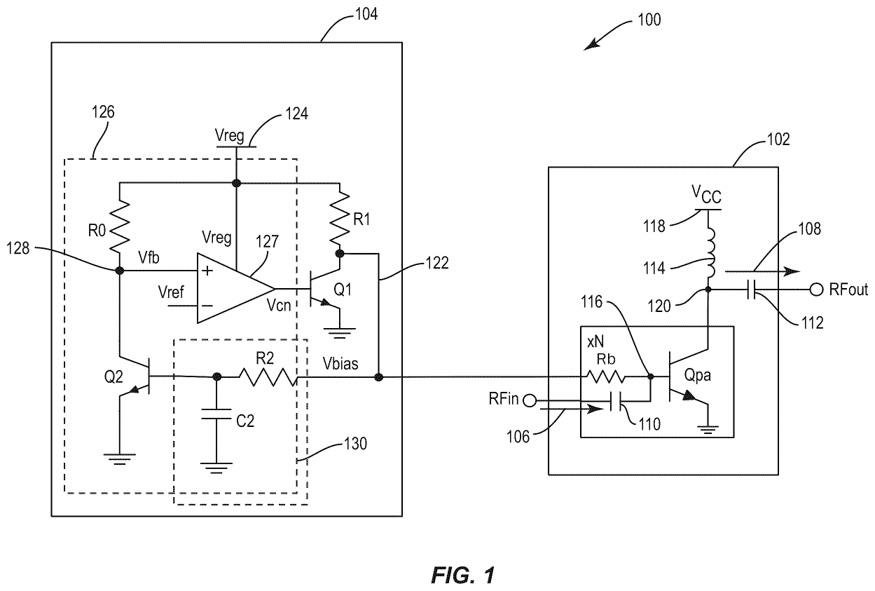

FIG. 1 illustrates a power amplification device 100 which includes a power amplification circuit 102 and a bias circuit 104. In some embodiments, the power amplification device 100 is formed as an integrated circuit (IC) on one or more semiconductor dies (not explicitly shown). In some embodiments, the semiconductor dies are provided in one or more IC packages.

The power amplification circuit 102 is configured to amplify an RF input signal 106 so as to generate an amplified RF output signal 108. The RF input signal 106 is amplified in accordance with a gain of the power amplification circuit 102 to generate the RF output signal 108. In some embodiments, the gain of the power amplification circuit 102 is greater than one.

The power amplification circuit 102 includes a power amplifier Qpa (also referred to as transistor Qpa or bipolar junction transistor (BJT) Qpa), an RF input terminal RFin, a capacitor 110, a capacitor 112, a resistor Rb, an inductor 114, and an RF output terminal RFout. The power amplification circuit 102 also defines a power amplifier input 116, a power node 118, and a power amplifier output 120.

In FIG. 1, the power amplifier Qpa is a Heterojunction Bipolar Transistor (HBT). The power amplifier Qpa includes a base, an emitter, and a collector. In FIG. 1, the base of the power amplifier Qpa is the power amplifier input 116, the collector of the power amplifier Qpa is the power amplifier output 120, and the emitter of the power amplifier Qpa is connected to ground. The power amplifier Qpa is configured to provide wideband amplification for the RF input signal 106. In one example, the power amplification circuit 102 is used as a WiFi power amplifier wherein the RF input signal 106 is in a bandwidth of between 5.15 Gigahertz (GHz) and 7.125 GHz with a modulation bandwidth of 160 Megahertz (MHz). The RF input signal 106 is received at the RF input terminal RFin and is filtered by the capacitor 110, which is connected in series between the RF input terminal RFin and the power amplifier input 116. The filtered Rf input signal 106 is then input into the power amplifier Qpa at the power amplifier input 116. The resistor Rb is configured to provide the appropriate matching resistance for the power amplifier Qpa, where the resistor Rb is connected in series between a bias node 122 in the bias circuit 104 and the power amplifier input 116.

The power amplifier Qpa is configured to output the RF output signal 108 from the power amplifier output 120. The power node 118 is configured to receive a power voltage Vcc, which powers the amplification of the RF input signal 106 by the power amplifier Qpa in order to generate the RF output signal 108. In some embodiments, the power voltage Vcc is a regulated power voltage and, in some embodiments, the power voltage Vcc is a power source voltage (e.g., the voltage generated directly from a battery). The inductor 114 is connected in series between the power node 118 and the power amplifier output 120. The inductor 114 thus serves as a direct current (DC) choke to isolate the power node 118 and the power amplifier Qpa. The capacitor 112 is connected in series between the power amplifier output 120 and the RF output terminal RFout. The capacitor 112 filters the RF output signal 108 and the filtered RF output signal 108 is output to downstream or external circuitry at the RF output terminal RFout.

The bias circuit 104 is configured to generate a bias voltage Vbias that is applied at the bias node 122. Since the bias node 122 is coupled to the power amplifier input 116 through the resistor Rb, the bias voltage Vbias is applied to the RF input signal 106 at the power amplifier input 116. The bias voltage Vbias thus sets a quiescent voltage at the power amplifier input 116. Since the resistance of the resistor Rb is set to be large in comparison to a resistance of the bias circuit 104 at the bias node 122, an input voltage at the power amplifier input 116 is thus approximately equal to the bias voltage Vbias plus a voltage of the filtered RF input signal 106.

The bias circuit 104 includes a power node 124, a feedback circuit 126, a BJT Q1, and a resistor R1. The power node 124 is configured to receive a power voltage Vreg (also referred to as a regulated voltage Vreg or a regulated supply voltage Vreg). In some embodiments, the regulated voltage Vreg is generated by a low drop out (LDO) voltage regulator. In some embodiments, a voltage level of the regulated supply voltage Vreg is between 1.8 Volts and 2.7 Volts.

The bias circuit 104 is a closed loop feedback style bias network that provides the BJT Q1 in a common emitter configuration. The common emitter configuration has a resistive load (R1) connected to a node configured to receive the regulated supply voltage (Vreg). The resistor R1 and the BJT Q1 are inside the feedback loop. This is advantageous due to the fact that the bias voltage Vbias generated by the BJT Q1 can be generated at a base-emitter voltage level (VBE) (for example, 1.3 Volts (V)). In some embodiments, the base voltage can easily be generated from a 2.5V supply. This meets the current specification in the market for low voltage operations. In some embodiments, the bias circuit 104 has a power voltage Vreg with a power level at approximately 1.5V. In prior approaches, an emitter follower configuration is used for amplifying a BJT, which requires a regulated voltage of 2.8V or greater.

In FIG. 1, the power voltage Vreg is a regulated voltage generated by a power regulation circuit. In other embodiments, the power voltage Vreg received at the power node 124 is a power source voltage (e.g., a voltage directly received from a battery).

The feedback circuit 126 includes a differential amplifier 127. The differential amplifier 127 is configured to receive a feedback input voltage Vfb at a feedback input node 128. The voltage level of the feedback input voltage Vfb indicates a voltage level of the bias voltage Vbias. Since there is an odd number of inversions in the bias circuit 104, the feedback input node 128 is connected to and the feedback input voltage Vfb is received at an inverting terminal of the differential amplifier 127. The differential amplifier 127 is configured to receive a reference voltage Vref. In FIG. 1, the reference voltage Vref is received at a non-inverting terminal of the differential amplifier 127.

The differential amplifier 127 is thus configured to generate a control voltage Vcn. The differential amplifier 127 is configured to set a voltage level of the control voltage Von based on a voltage level of the feedback input voltage Vfb and a voltage level of the reference voltage Vref. In some embodiments, the differential amplifier 127 is configured to set a voltage level of the control voltage Von so that the voltage level of the feedback input voltage Vfb and the voltage level of the reference voltage Vref are equal to one another. Thus, the differential amplifier 127 adjusts the voltage level of the control voltage Von in response to a change in the voltage level of the feedback input voltage Vfb until the voltage level of the feedback input voltage Vfb is again equal to the voltage level of the reference voltage Vref.

The feedback circuit 126 further includes a resistor R0, a dominant pole filter 130, and a BJT Q2. The resistor R1 is connected between the power node 124 and the bias node 122. The dominant pole filter 130 is connected between the bias node 122 and a base of the BJT Q2. The dominant pole filter 130 is configured to set a dominant pole of the feedback loop created by the feedback circuit 126. The dominant pole filter 130 filters the bias voltage Vbias, which is then applied to the base of the BJT Q2. In this embodiment, the dominant pole filter 130 includes a resistor R2 connected in series between the bias node 122 and the base of the BJT Q2. A capacitor C2 is coupled in shunt with respect to the base of the BJT Q2. An emitter of the BJT Q2 is coupled to ground.

The resistor R0 is connected in series between the power node 124 and the feedback input node 128. A collector of the BJT Q2 is connected to the feedback input node 128. As such, the resistor R0 and the BJT Q2 are configured to generate the feedback input voltage Vfb. Since the filtered bias voltage Vbias is received at the base of the BJT Q2, the voltage level of the feedback input voltage Vfb is a function of the voltage level of the bias voltage Vbias.

The bias circuit 104 further includes the BJT Q1 and the resistor R1. In FIG. 1, the resistor R1 is connected in series between the power node 124 and the bias node 122. The base of the BJT Q1 is connected to an output terminal of the differential amplifier 127. Thus, the base of the BJT Q1 is configured to receive the control voltage Von. The emitter of the BJT Q1 is coupled to ground. Accordingly, the BJT Q1 is in a common emitter configuration. The BJT Q1 thus provides an inversion of the voltage when generating the bias voltage Vbias.

The feedback circuit 126 is configured to force the feedback voltage Vfb to be approximately equal to the reference voltage Vref (e.g., equal to or plus or minus an offset voltage). Accordingly, the current level of the current across the resistor R0 is approximately equal to

$$\frac{Vreg - Vref}{R 0} .$$

A collector current in the BJT Q2 is equal to the current across the resistor R0, wherein the feedback circuit 126 forces this to be true (if we ignore a base current from the differential amplifier 127). The feedback loop created by the feedback circuit 126 forces the voltage Vbias on the bias node 122 to create the correct collector current in the BJT Q2 that is approximately equal to

$$\frac{Vref - Vfb}{R 0} .$$

The net effect of the feedback loop provided by the feedback circuit 126 is to create an active current mirror where the collector current in the transistor Qpa is approximately a scaled version of the current through the collector of the BJT Q2.

With respect to the feedback loop, the differential amplifier 127 is configured to generate the control voltage Von. The voltage level of the control voltage Von is received by the base of the BJT Q1. The control voltage Von is generated such that the differential amplifier 127, the BJT Q1, and the resistor R1 force the feedback input voltage Vfb to be approximately be equal to the reference voltage Vref such that the current level of the current across the resistor R0 is approximately equal to

$$\frac{Vreg - Vref}{R 0} .$$

The control voltage Von is set so that the BJT Q1 is off when the maximum current level of the base current is being drawn by the power amplifier Qpa. As the current level of the base current decreases, the differential amplifier 127 is configured to generate the control voltage Von so that the BJT Q1 is turned on so as to draw some of the current through the BJT Q1. To do this, the differential amplifier 127 is configured to generate the control voltage Von with the voltage level set so that the current level of the current running through the resistor R0 is set to be at a fixed proportion with respect to the current level of the current across the resistor R1.

Since the BJT Q1 is in a common emitter configuration, the bias voltage Vbias generated at the bias node 122 can be as low as 1 VBE (e.g., 1.3V). As such, the voltage level of the power voltage Vreg at the power node 124 can easily be as low as 1.5V to 2V. A voltage level of the power voltage Vreg between 1.5V to 2V provides an adequate margin for the bias voltage Vbias to be generated at the appropriate voltage level. In one embodiment, the voltage level of the power voltage Vreg is 2V, the voltage level of the control voltage Von is on average 1.3V, and the voltage level of the bias voltage Vbias is approximately 1.3V, which is equivalent to 1 VBE. In some embodiments, the power amplification device 100 is thus configured to operate with the power voltage Vreg being provided at a lower voltage level (e.g., 2.5V to 3V or a multiple of 1.5 VBE to 2 VBE).

In some embodiments, the BJT Q2 and the power amplifier Qpa are thermally coupled to one another. This ensures that the feedback circuit 126 adjusts the currents generated in accordance with the operating temperature of the power amplifier Qpa.

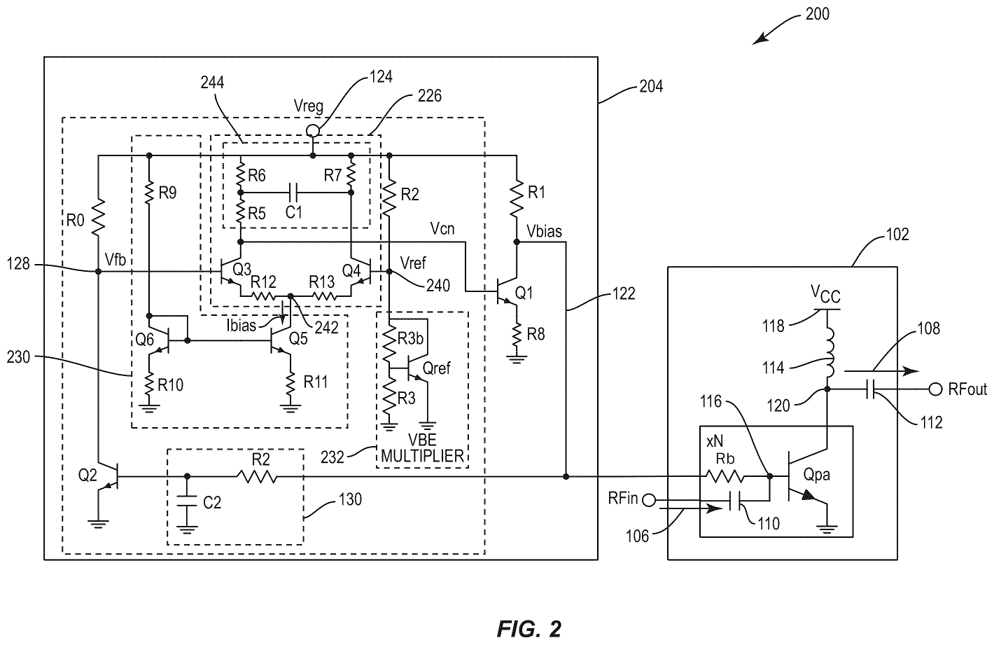

FIG. 2 illustrates a power amplification device 200, in accordance with some embodiments.

The power amplification device 200 includes the same power amplification circuit 102 as described above with respect to FIG. 1. The power amplification device 200 also includes a bias circuit 204. The bias circuit 204 includes the same power node 124, resistor R0, resistor R1, feedback input node 128, BJT Q1, BJT Q2, and dominant pole filter 130, all as described above with respect to FIG. 1. The bias circuit 204 further includes a differential amplifier 226. In some embodiments, the differential amplifier 127 as shown in FIG. 1 is provided in the same manner as the differential amplifier 226 as shown in FIG. 2. The bias circuit 204 further includes a differential pair biasing circuit 230 and a VBE multiplying circuit 232.

The differential amplifier 226 includes a differential pair of BJTs Q3, Q4. A base of the BJT Q3 is connected to the feedback input node 128 in order to receive the feedback input voltage Vfb. A base of the BJT Q4 is connected to a reference node 240 in order to receive the reference voltage Vref. An emitter of the BJT Q3 is coupled to a bias node 242 through a resistor R12. The resistor R12 is thus connected between the emitter of the BJT Q3 and the bias node 242. An emitter of the BJT Q4 is coupled to the bias node 242 through a resistor R13. The resistor R13 is thus connected between the emitter of the BJT Q4 and the bias node 242. The bias node 242 is configured to receive a bias current Ibias wherein the bias current Ibias biases the differential pair of BJTs Q3, Q4 in the differential amplifier 226. The collector of the BJT Q3 is coupled to the power node 124 through a lead lag circuit 244. Additionally, the collector of the BJT Q4 is coupled to the power node 124 through the lead lag circuit 244. The control voltage Von is generated at the collector of the BJT Q3.

In response to the feedback input voltage Vfb being equal to the reference voltage Vref, a current that flows through the collector of the BJT Q3 and a current that flows through the collector of the BJT Q4 are equal to one another. The BJT Q3 thus does not change a voltage level of the control voltage Vcn.

However, in response to the feedback input voltage Vfb not being equal to the voltage level of the reference voltage Vref, the current that flows though the collector of the BJT Q3 and the current that flows through the collector of the BJT Q4 also are not equal to one another. Accordingly, the BJT Q3 is configured to adjust the voltage level of the control voltage Von until the voltage level of the feedback input voltage Vfb again becomes equal to the voltage level of the reference voltage Vref. Accordingly, if either the voltage level of the feedback input voltage Vfb or the voltage level of the reference voltage Vref change, the voltage level of the control voltage Von also changes.

The lead lag circuit 244 and the resistors R12, R13 have been added to the differential amplifier 226 to stabilize the feedback loop and to reduce a gain of the differential amplifier 226. The lead lag circuit 244 includes a resistor R5, a resistor R6, a resistor R7, and a capacitor C1. The resistor R6 is connected in series between the power node Vreg and a first end of the capacitor C1. The resistor R5 is connected in series between the first end of the capacitor C1 and the collector of the BJT Q3. The resistor R7 is connected in series between the power node 124 and a second end of the capacitor C1. The second end of the capacitor C1 is connected to the collector of the BJT Q4. The lead lag circuit 244 is configured to remove undesired frequency responses in the feedback loop and thereby stabilize the differential amplifier 226.

The differential pair biasing circuit 230 in FIG. 2 is configured to generate the bias current Ibias at the bias node 242 that biases the differential amplifier 226. The differential pair biasing circuit 230 is a current mirror that is formed by a BJT Q5, a BJT Q6, and a resistor R9. The BJT Q5 has a collector connected to the bias node 242, a base that is connected to the base of the BJT Q6, and an emitter that is coupled to ground through a resistor R11. The BJT Q6 is in a diode configuration and has the collector of the BJT Q6 directly connected to the base of the BJT Q6. The resistor R9 is connected in series between the power node 124 and the collector of the BJT Q6. The emitter of the BJT Q6 is coupled to ground through a resistor R10. As such, the bias current Ibias is generated through the resistor R9 into the collector of the BJT Q6.

The resistors R10, R11 increase the accuracy of the current mirror provided by the differential pair biasing circuit 230 in FIG. 2 and make the differential pair biasing circuit 230 less sensitive to temperature and mismatch between the BJT Q5, BJT Q6. The capacitors C1, C2 provide filtering to stabilize the feedback loop. The resistor R2 is connected in series between the power node 124 and the reference node 240 to help reduce the closed loop gain of the bias circuit 204. Furthermore, the emitter of the BJT Q1 is coupled to ground through a resistor R8. The resistor R8 also helps to reduce the loop gain.

The power amplification device 200 also includes the VBE multiplying circuit 232. The VBE multiplying circuit 232 is configured to generate the reference voltage Vref at the reference node 240 such that the reference voltage Vref is a multiple of VBE (i.e., the turn on voltage of a BJT). The VBE multiplying circuit 232 includes a BJT Qref, a resistor R3, and a resistor R3b. An emitter of the BJT Qref is connected to ground. A collector of the BJT Qref is connected to the reference node 240. The resistor R3b is connected in series between the reference node 240 and the base of the BJT Qref. The resistor R3 is connected in series between the base of the BJT Qref and ground.

In some embodiments, the reference voltage Vref is a temperature dependent reference voltage. This allows us to manipulate the temperature coefficient of the current through the resistor R0 and, therefore, the collector of BJT Q2 and current in the transistor Qpa. If no temperature coefficient is desired, then the BJT Qref is removed and the reference voltage Vref is simply a potential division of the power voltage Vreg set by (R3+R3b)/(R3+R3b+R2).

If the reference voltage Vref is to be a multiple of VBE, the resistor R3b and the resistor Rb set the multiple. In some embodiments, the resistor R3b and the resistor Rb set the multiple to be equal to 1.5 such that the voltage level of the reference voltage Vref is equal to 1.5×VBE.

As explained above, if either the voltage level of the feedback input voltage Vfb or the voltage level of the reference voltage Vref change, the voltage level of the control voltage Von also changes. Whether or not a temperature coefficient is put on the reference voltage Vref depends on whether a constant current or some other temperature dependance is desired for the current of the transistor Qpa in order to meet the linearity and/or gain requirements of the power amplification circuit 102. However, changes in temperature can result in the voltage level of the reference voltage Vref to be adjusted. It is desirable that these changes in the voltage level of the reference voltage Vref to be in line with the operation of the remainder of the power amplification device 200. Accordingly, in some embodiments, the BJT Qref, the power amplifier Qpa, and the BJT Q2 are thermally coupled to one another. In some embodiments, the BJT Qref, the power amplifier Qpa, and the BJT Q2 are formed close to one another so that the temperature of the BJT Qref, the power amplifier Qpa, and the BJT Q2 is provided so as to be relatively constant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A power amplification device, comprising:
a power node configured to receive a power voltage;
a power amplifier that includes a power amplifier input configured to receive a radio frequency (RF) input signal; and
a bias circuit comprising:
a feedback circuit configured to receive a feedback input voltage that indicates a bias voltage applied to the power amplifier input of the power amplifier and to receive a reference voltage;
a bias node coupled to the power amplifier input, wherein the bias voltage applied to the power amplifier input is generated at the bias node;
a bipolar junction transistor (BJT) in a common emitter configuration, wherein the BJT includes a base connected to receive a control voltage from the feedback circuit, an emitter, and a collector, wherein the collector is coupled to the bias node;
a resistor connected between the power node and the bias node; and
wherein the feedback circuit is configured to generate the control voltage such that the bias voltage is set in accordance with the reference voltage.

2. The power amplification device of claim 1, wherein an input voltage is generated from the bias voltage generated at the bias node and the RF input signal applied to the power amplifier input.

3. The power amplification device of claim 1, wherein the emitter is connected to ground.

4. The power amplification device of claim 1, wherein:
the power amplifier is a Heterojunction Bipolar Transistor (HBT) having a second base, a second emitter, and a second collector;
the base is a first base, the emitter is a first emitter, and the collector is a first collector;
the power amplifier input is the second base; and
the bias circuit is configured to receive a regulated voltage and the regulated voltage is between 1.8 Volts and 2.7 Volts.

5. The power amplification device of claim 1, wherein the feedback circuit comprises a differential amplifier configured to receive the feedback input voltage and the reference voltage, wherein the differential amplifier is further configured to generate the control voltage such that the bias voltage is set in accordance with the reference voltage.

6. The power amplification device of claim 5, further comprising:
a second resistor connected between the power node and a feedback input node, wherein the differential amplifier is configured to receive the feedback input voltage at the feedback input node and wherein the resistor is a first resistor; and
a second BJT having a second base, a second collector, and a second emitter, wherein:
the base is a first base, the collector is a first collector, and the emitter is a first emitter;
the second base is coupled to the first base;
the second collector is connected to the feedback input node; and
the second emitter is connected to ground.

7. The power amplification device of claim 6, wherein a dominant pole filter is connected between the second base and the power amplifier input.

8. The power amplification device of claim 5, wherein the BJT is a first BJT, the base is a first base, the emitter is a first emitter, and the collector is a first collector, and wherein the differential amplifier comprises:
a second BJT and a third BJT that form a differential pair;
the second BJT has a second base that is configured to receive the feedback input voltage, a second collector that is coupled to the power node, and a second emitter that is connected to a differential pair biasing node that receives a second bias voltage, the bias voltage being a first bias voltage; and
the third BJT has a third base that is configured to receive the reference voltage, a third collector that is coupled to the power node, and a third emitter that is connected to the differential pair biasing node that receives the second bias voltage.

9. The power amplification device of claim 8, wherein the feedback circuit further comprises a differential pair biasing circuit that is configured to generate a bias current.

10. The power amplification device of claim 9, wherein the differential pair biasing circuit comprises a current mirror that includes:
a fourth BJT having a fourth collector connected to the differential pair biasing node, a fourth emitter coupled to ground, and a fourth base;
a fifth BJT having a fifth base connected to the fourth base, a fifth collector directly connected to the fifth base, and a fifth emitter coupled to the ground; and
a third resistor connected between the power node and the fifth collector.

11. The power amplification device of claim 1, further comprising a base-emitter voltage level (VBE) multiplying circuit configured to generate the reference voltage as a temperature dependent reference voltage.

12. The power amplification device of claim 11, wherein the resistor is a first resistor, the BJT is a first BJT, the base is a first base, the collector is a first collector, the emitter is a first emitter, and wherein the VBE multiplying circuit comprises:
a second resistor;
a third resistor;
a second BJT having a second base, a second collector, and a second emitter; and
wherein:
the second collector is connected to the feedback circuit such that the reference voltage is generated at the second collector;
the second resistor is connected between the second collector and the second base; and
the third resistor is connected between the second base and ground.

13. The power amplification device of claim 12, wherein the second BJT is thermally coupled to the power amplifier and the bias circuit.

14. A power amplification device, comprising:
a power node configured to receive a power voltage;
a Heterojunction Bipolar Transistor (HBT) that includes a first base configured to receive a radio frequency (RF) input signal, a first collector configured to output an RF output signal, and a first emitter connected to ground; and
a bias circuit comprising:
a feedback circuit configured to receive a feedback input voltage that indicates a bias voltage applied to the first base of the HBT and to receive a reference voltage;
a resistor coupled to the power node;
a bipolar junction transistor (BJT) in a common emitter configuration, wherein the BJT includes a second base connected to receive a control voltage from the feedback circuit, a second emitter coupled to the ground, and a second collector, wherein the second collector and the resistor are connected to apply the bias voltage to the first base; and
wherein the feedback circuit is configured to generate the control voltage such that the bias voltage is set in accordance with the reference voltage.

15. The power amplification device of claim 14, wherein the feedback circuit comprises a differential amplifier configured to receive the feedback input voltage and the reference voltage, wherein the differential amplifier is further configured to generate the control voltage such that the bias voltage is set in accordance with the reference voltage.

16. The power amplification device of claim 15, further comprising:
a second resistor connected between the power node and a feedback input node, wherein the differential amplifier is configured to receive the feedback input voltage at the feedback input node and wherein the resistor is a first resistor; and
a second BJT having a third base, a third collector, and a third emitter, wherein:
the third base is coupled to the first base;
the third collector is connected to the feedback input node; and
the third emitter is connected to the ground.

17. The power amplification device of claim 15, wherein a dominant pole filter is connected between a third base and a power amplifier input.

18. The power amplification device of claim 15, wherein the BJT is a first BJT and wherein the differential amplifier comprises:
a second BJT and a third BJT that form a differential pair;
the second BJT has a third base that is configured to receive the feedback input voltage, a third collector that is coupled to the power node, and a third emitter that is connected to a differential pair biasing node that receives a second bias voltage, the bias voltage being a first bias voltage; and
the third BJT has a fourth base that is configured to receive the reference voltage, a fourth collector that is coupled to the power node and a fourth emitter that is connected to the differential pair biasing node that receives the second bias voltage.

19. The power amplification device of claim 18, wherein the feedback circuit further comprises a differential pair biasing circuit that is configured to generate the second bias voltage.

20. The power amplification device of claim 14, wherein the bias circuit is configured to receive a regulated voltage and the regulated voltage is between voltage of the HBT is between 1.8 Volts and 2.7 Volts.
